(19) United States
(12) Patent Application Publication
(10) Pub. No.: US 2010/0227083 A1
(43) Pub. Date: Sep. 9, 2010

(54) Nanoscale Oxide Coatings

(75) Inventors: Shriram Ramanathan, Acton, MA (US); Chia-Lin Chang, Somerville, MA (US)

Correspondence Address: Elizabeth Eunjoo Kim, Rauschenbach Patent Law Group, LLP, 43 Hackensack Road, Chestnut Hill, MA, 02467, US

(73) Assignee: PRESIDENT AND FELLOWS OF HARVARD COLLEGE, Cambridge, MA (US)

(21) Appl. No.: 12/519,168

(22) PCT Filed: Dec. 18, 2007
(86) PCT No.: PCT/US07/87895

§ 371 Date: Apr. 14, 2010

Related U.S. Application Data
(60) Provisional application No. 60/870,440, filed on Dec. 18, 2006.

(51) Int. Cl. C23C 8/10; C23C 14/08

(52) U.S. Cl. 427/595

(57) ABSTRACT

In various aspects, the present inventions provide methods for forming corrosion resistant oxide coatings on metals and/or improving the corrosion resistance of existing native oxide coatings. In various aspects, provided are methods for forming corrosion resistant oxide coatings on metals surfaces that are immersed in an aqueous solution. Various embodiments of various aspects of the present inventions can provide a scalable process for the formation of corrosion resistant coatings on metals in a manner that does not require high-vacuum technology, can be adapted to large structures, such as ships or aircraft, and in various aspects and embodiments can improve quality of existing oxide films on a metal or alloy surface.

### CROSS-REFERENCE TO RELATED APPLICATIONS

The present application claims the benefit of and priority to copending U.S. Provisional Patent Application No. 60/870,440, filed Dec. 18, 2006, the entire contents of which are herein incorporated by reference.

### GOVERNMENT RIGHTS

This invention was made with support from the Office of Naval Research under Award No. N00014-07-1-0486. The U.S. government may have certain rights in this invention.

### BACKGROUND

Corrosion can be a problem in many technologies, ranging from medical implants to large-scale naval vessels, aircraft, and oil pipelines. Corrosion can be defined as damage to a material resulting from its exposure to the environment in which it is used. The physical process can occur when metallic surfaces or objects are left to directly interact with air or a solution, and primarily stems from the formation of a pit over the metallic surface as a result of contact with a liquid or an oxygenated gaseous entity. The rate at which a metallic object corrodes is highly dependent on the type of environment to which it is exposed, as well as the chemical composition of the metal or alloy. Corrosive effects are present in our everyday lives because of the enormous amount of metallic material in use. A 2002 study of the US Federal Highway Administration estimated the cost of corrosion of metallic materials to be $276 billion, approximately 3.1% of national Gross Domestic Product (GDP).

Aluminum is among the most important metals for several engineering technologies. Several methods and techniques have been investigated to retard the corrosion-induced damage of aluminum, including artificial deposition of protective coatings. Surface-alloying of aluminum through the ion implantation of selected elements (such as Si, Cr, Zr, Nb, Mo, Zn, and Mg) may be adopted for the enhancement of corrosive resistance of aluminum. The elements are typically chosen based on their capacity for chloride ion adsorption of an oxide covered material. Because the ion implementation's modified region might be relatively shallow, physical vapor deposition methods have been used to coat oxide layers, such as tantalum oxide, on the implanted surfaces. However, such methods often require the material to be treated within an enclosed apparatus under highly controlled gaseous environment conditions.

### SUMMARY

In various aspects, the present inventions provide methods for forming an oxide coating on a metal surface to provide corrosion resistance to the metal; methods for improving the corrosion resistance of pre-existing oxide coatings on metals; and methods for creating corrosion resistant metal oxide coatings on metal surfaces immersed in aqueous solutions (e.g., fresh water, salt water, etc.).

In various aspects, the present inventions provide methods for providing a corrosion resistant oxide coating on a metal surface. In various embodiments, the methods comprise irradiating a metal surface in the presence of oxygen with light having one or more wavelengths in the range between about 100 nm to 365 nm and a power density greater than about 10 mW/cm² to form an oxide layer on the metal surface. In various embodiments, the metal surface is cleaned prior to irradiation to substantially remove any existing metal oxide layer.

In practice, many metals form an oxide layer on their surface as they corrode. If the oxide layer inhibits further corrosion, the metal is said to passivate. In some cases, local areas of the passive film break down allowing significant metal corrosion to occur in a small area. This phenomena is called pitting corrosion or simply pitting. Accordingly, many naturally occurring metal oxide layers provide diminished corrosion resistance.

In various aspects, the present inventions provide methods for improving the corrosion resistance of pre-existing oxide coatings on metals. In various embodiments, the methods comprise providing a metal surface having a metal oxide layer thereon and irradiating the metal oxide coating in the presence of oxygen to light having one or more wavelengths in the range between about 100 nm to 365 nm and a power density greater than about 10 mW/cm² to form a modified oxide layer on the metal surface.

In various embodiments, the improvement to the pre-existing metal oxide layer comprises forming a modified oxide layer having one or more of: (a) an impedance that is at least four times greater than the impedance of the metal oxide layer prior to irradiation; (b) an impedance that is at least five times greater than the impedance of the metal oxide layer prior to irradiation; (c) an impedance that is at least six times greater than the impedance of the metal oxide layer prior to irradiation; (d) an impedance that is at least seven times greater than the impedance of the metal oxide layer prior to irradiation; (e) an impedance that is at least ten times greater than the impedance of the metal oxide layer prior to irradiation; (f) a leakage current that is at least 10 times less than the leakage current of the metal oxide layer prior to irradiation; (g) a leakage current that is at least 50 times less than the leakage current of the metal oxide layer prior to irradiation; (h) a leakage current that is at least 100 times less than the leakage current of the metal oxide layer prior to irradiation; (i) a leakage current that is at least 400 times less than the leakage current of the metal oxide layer prior to irradiation; (j) a pitting potential that is at least 20% greater than the pitting potential of the metal oxide layer prior to irradiation; (k) a pitting potential that is at least 25% greater than the pitting potential of the metal oxide layer prior to irradiation; (l) a pitting potential that is at least 30% greater than the pitting potential of the metal oxide layer prior to irradiation; and/or (m) a pitting potential that is at least 40% greater than the pitting potential of the metal oxide layer prior to irradiation.

In various embodiments of the various aspects of the present inventions, the thickness of the metal oxide layer can be controlled by temperature and oxygen partial pressure. Higher oxygen partial pressures and higher temperatures favor the formation of thicker metal oxide layers. In various embodiments of the various aspects of the present invention, the oxygen partial pressure is one or more of: (a) in the range between about 1 mTorr to about 1000 Torr; (b) in the range between about 10 mTorr to about 100 mTorr; (c) in the range between about 1 Torr to about 100 Torr; (d) in the range between about 100 Torr to about 200 Torr; (e) in the range between about 200 Torr to about 300 Torr; and/or (f) greater than about 300 Torr. Oxygen can be provided in a variety of forms and/or sources for use in the present invention including, but not limited to, oxygen gas, air, impure nitrogen, and steam.

In various aspects, the present inventions provide methods for creating corrosion resistant metal oxide coatings on metal surfaces immersed in aqueous solutions (e.g., fresh water, salt water, etc.). In various embodiments, the methods comprise providing a substrate having a metal surface, at least a portion of the metal surface being immersed in an aqueous solution; and irradiating at least the portion of the metal surface immersed in water with light having one or more wavelengths in the range between about 100 nm to 365 nm and a power density greater than about 10 mW/cm² to form an oxide layer on the metal surface.

In various embodiments of the various aspects of the present inventions, the metal surface comprises one or more of aluminum, chromium, iron, magnesium, titanium and alloys thereof.

In various embodiments of the various aspects of the present inventions, the methods comprise irradiating the metal surface and/or oxide layer on said surface with light having one or more wavelengths in the range between about 100 nm to 365 nm to provide a metal oxide coated surface for one or more of the following time periods: (a) greater than about 10 minutes; (b) in the range between about 10 minutes to about 270 minutes; (c) in the range between about 10 minutes to about 240 minutes; (d) in the range between about 10 minutes to about 180 minutes; (f) in the range between about 10 minutes to about 120 minutes; (b) in the range between about 10 minutes to about 90 minutes; (g) less than about three hours; and/or; (g) less than about four hours.

In various embodiments of the various aspects of the present invention, the methods comprise irradiating the metal surface and/or oxide layer on said surface with light having one or more wavelengths in the range between about 100 nm to 365 nm with light having a power density within this range of wavelengths of greater than about one or more of: about 5 mW/cm², about 10 mW/cm², about 20 mW/cm², about 40 mW/cm², about 60 mW/cm², about 80 mW/cm², about 100 mW/cm², about 200 mW/cm², about 400 mW/cm², about 600 mW/cm², and/or about 1 W/cm². In various embodiments, the light source comprises an incoherent source, such as, for example, a UV lamp, e.g., a mercury lamp. In various embodiments, the light source comprises an coherent source, such as, for example, a laser.

In various embodiments of the various aspects of the present invention, the methods provide an aluminum oxide (Al₂O₃) layer on a metal surface, the aluminum oxide layer having one or more of: (a) an impedance of greater than about 100,000 ohms; (b) an impedance of greater than about 150,000 ohms; and/or a (c) pitting potential of greater than about −0.675 V.

The forgoing and other aspects, embodiments, and features of the inventions can be more fully understood from the following description in conjunction with the accompanying drawings. In the drawings like reference characters generally refer to like features and structural elements throughout the various figures. The drawings are not necessarily to scale, emphasis instead being placed upon illustrating the principles of the inventions.

### BRIEF DESCRIPTION OF THE DRAWINGS

FIG. 1 presents electrochemical impedance spectra of aluminum oxidized by UV light and under natural lighting (with no-UV light involved) as a function of oxidation time. Both UV and natural oxidations are performed at substantially the same pressure level of 760 Torr and at the room temperature in the load-lock of the apparatus described in the Examples. The equivalent circuit adopted to characterize the oxide film on aluminum/silicon in the 0.5M NaCl solution for 1 hour is shown as an inset in FIG. 1 where: Rₒ: resistance of the oxide; Cₒ: capacitance of the oxide; Rₛ: resistance of the electrolyte solution (0.5M NaCl in this example).

FIG. 2 presents Tafel plots of two representative samples, upper plot: a 240-minute, natural-oxidized aluminum/silicon sample and, lower plot: a 120 minute UV oxidized sample.

FIG. 3 presents Nyquist plots of Z′ vs. Z″ for various UV light compensated native oxides and UV grown oxides as a function of UV exposure time.

FIG. 4. presents data plots of resistance and oxide thickness on the various oxides of FIG. 3 for UV light compensated native oxides and UV-grown oxide.

### DETAILED DESCRIPTION OF VARIOUS EMBODIMENTS

The present inventions, in various aspects, provide methods for creating corrosion resistant metal oxide coatings on metals; methods for improving the corrosion resistance of pre-existing oxide coatings on metals; and methods for creating corrosion resistant metal oxide coatings on metal surfaces immersed in aqueous solutions (e.g., fresh water, salt water, etc.).

As used herein, the term “metal” refers to magnesium (Mg), aluminum (Al), calcium (Ca), scandium, (Sc), titanium (Ti), vanadium (V), chromium (Cr), manganese (Mn), iron (Fe), cobalt (Co), nickel (Ni), copper (Cu), and zinc (Zn).

The present inventions, in various embodiments, provide methods for forming metal oxide layers on a metal surface and/or modifying an existing metal oxide layer. The thickness of the metal oxide layer can be controlled by controlling the temperature and/or oxygen partial pressure during irradiation. Higher oxygen partial pressures and higher temperatures favor the formation of thicker metal oxide layers.

The inventors have surprisingly found that irradiation of a metal surface in the presence of oxygen with light having one or more wavelengths in the range between about 100 nm to 365 nm and a power density greater than about 10 mW/cm² in this wavelength range can form an oxide layer on the metal surface that provides corrosion resistance.

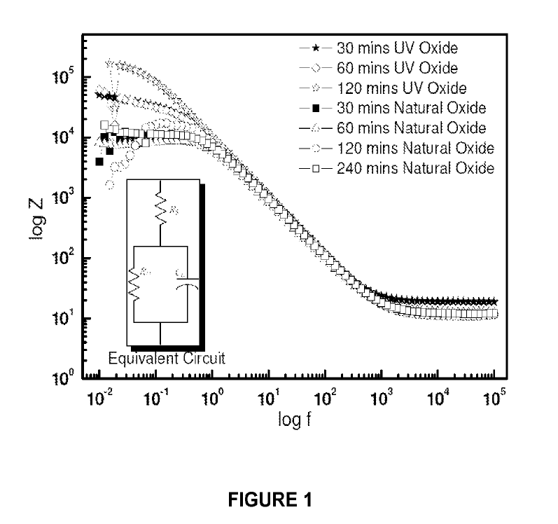

The corrosion resistance provided by a metal oxide surface can be evaluated by several parameters. One parameter is the impedance of the metal oxide surface. Metal oxide surface impedance can be measured, e.g., using electrochemical impedance spectroscopy (EIS). The impedance of the “cell” comprising the metal oxide surface can be described by an equivalent circuit, e.g. as soon in the inset to FIG. 1. This circuit can be represented by the formula:

$$Z = {R}_{s} + \frac{{R}_{o}}{{( 1 + ω {R}_{o} {C}_{o} )}^{2}} + \frac{j ( - ω {R}_{o}^{2} {C}_{o} )}{[ 1 + {( ω {R}_{o} {C}_{o} )}^{2} ]} \qquad ( 1 )$$

where Z is the total impedance in ohms Rₒ, (ohms) and Rₛ (ohms) represent, respectively, the resistance of the metal oxide and of the electrolyte solution and Cₒ (farads) is the capacitance of the metal oxide, and ω=2πf where f is the ac frequency in Hz.

In various embodiments, the impedance of a metal oxide layer is the impedance as determined by electrochemical impedance spectroscopy (EIS) using a description of the circuit that can be represented an equation mathematically equivalent to Equation (1).

Referring to FIG. 1, EIS spectra for various metal oxide films formed on aluminum under various synthesis conditions are shown. Equation (1) fits to the EIS spectra of FIG. 1 are summarized in Table 1. In the data of Table 1, the electrolyte solution was 0.5M NaCl. The oxide thickness, d, was evaluated according to the fitted oxide capacitance

$${C}_{o} = \frac{ɛ {ɛ}_{0} A}{d} \qquad ( 2 )$$

where A is the sample area in units of cm² (3 cm² in the data of FIG. 1); ∈₀=8.85×10⁻¹⁴ F/cm; and ∈ is the dielectric constant of the metal oxide film.

The conditions for formation of the metal surface, metal oxide films and measurements, for the data of Table 1, and FIGS. 1-4, were as described in the Examples.

TABLE 1

| | Rₒ (ohms) | Cₒ (F) | d (Å) |
|---|---|---|---|
| 30 min Natural Oxide | 11000 | 1.45E−5 | 17 |
| 60 min Natural Oxide | 9100 | 1.70E−5 | 14 |
| 120 min Natural Oxide | 17000 | 1.40E−5 | 17 |
| 240 min Natural Oxide | 11400 | 1.50E−5 | 16 |
| 30 min UV Oxide | 31500 | 1.47E−5 | 16 |
| 60 min UV Oxide | 30500 | 1.51E−5 | 16 |
| 120 min UV Oxide | 150000 | 1.34E−5 | 18 |

The resistance, Rₒ, is not significantly enhanced by the increase in oxidation time for the natural oxidation conditions as shown in FIG. 1 and Table 1. This indicates that the metal oxide layer quality formed by natural oxidation is not influenced by longer oxygen exposures at room temperature according to the unchanged impedance in the similar thickness range.

Different properties were observed for aluminum oxidized under photon irradiation at room temperature according to various embodiments of the present inventions. For example, referring to FIG. 1 and Table 1, the impedance of Al₂O₃ grown under UV irradiation for one hour is enhanced nearly three times, compared to the natural grown oxide. With an additional hour (for a total of 120 minutes) of aluminum UV oxidation, the EIS spectra reveals an increase in resistance, which is approximately 15 times larger than native oxide as seen in Table 1. Superior resistance behavior against exposure of 0.5M NaCl solution is exhibited after the aluminum is oxidized via UV exposure at room temperature for 120 minutes. Because natural and UV oxides have almost the same oxide thickness range (see, e.g., last column of Table 1), it is believed, without being held to theory, that UV light irradiation in accordance with various embodiments of the present inventions generates a denser oxide, with reduced oxygen point defects and greater resistance to ion migration.

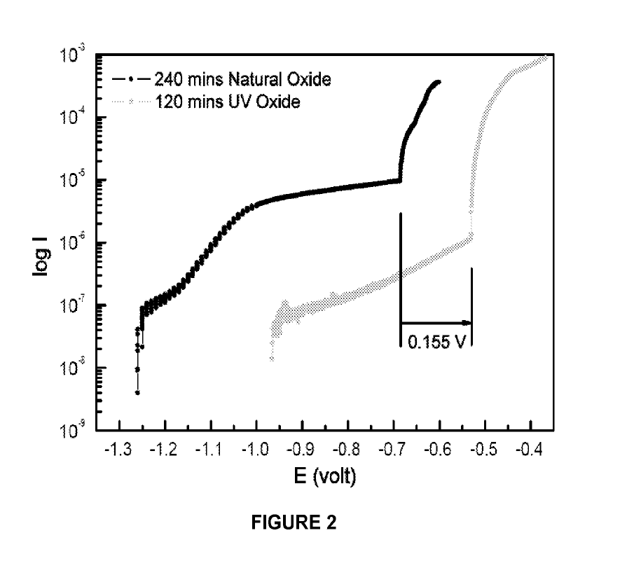

The corrosion resistance provided by a metal oxide surface can also be evaluated by the size of pore pathways; which effect the rate of corrosion and the diffusion of chloride ions. Thus, a denser structure can provide greater oxide resistance to the transportation of ions and electrons. To evaluate this corrosion resistance, linear polarization measurements, using Tafel analysis, were performed on UV- and native-grown oxides to compare their performance in a corrosive environment. In the metal oxide coated region, shown in FIG. 2, the UV-grown oxide exhibits two orders of magnitude reduction in leakage current, compared to the native-grown oxide. In addition, the pitting potential for the UV-grown oxide is 0.155 V higher than that of the native-grown oxide, indicating superior oxide film stability in the presence of corrosives.

In various embodiments, the leakage current of a metal oxide layer is the leakage current as determined by linear polarization measurements using Tafel analysis. For example, using Tafel equations for both the anodic and cathodic reactions in a corrosion system. In various embodiments, the leakage current can be measured using a capacitor structure and measuring d.c. current flow across the metal oxide layer.

In various embodiments, the pitting potential of a metal oxide layer is the pitting potential as determined by the breakdown of the oxide. V In various embodiments, the pitting potential of a metal oxide layer is the pitting potential as determined by measurement standard ASTM F2129.

In various aspects, the present inventions provide methods for improving the corrosion resistance properties of a metal surface already having an existing natural metal oxide coating.

Following a natural oxidation process, UV exposures were performed at room temperature for times ranging from 1 to 120 minutes. The natural metal oxide layers treated by these methods are referred to by the shorthand “UV-compensated native oxides” in the figures and below for conciseness of reference.

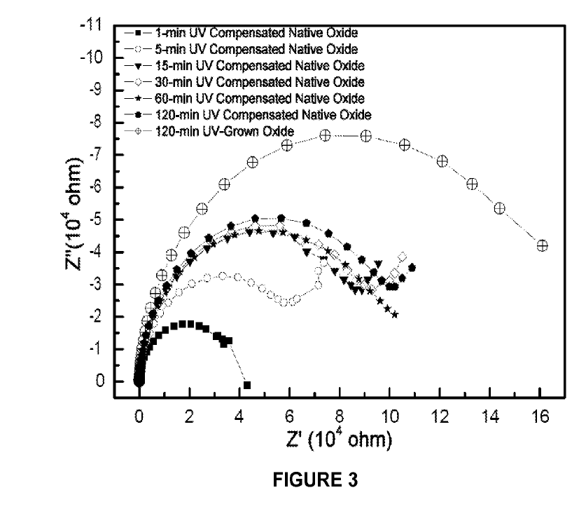

Referring to FIG. 3, a Nyquist plot of Z″ vs. Z′ for UV exposure on the native oxide was used to measure the time evolution of impedance. The outermost semicircle representing the Nyquist plot for a 120-minute, UV-grown oxide with resistance of 0.15 MΩ (Table 1) is included in FIG. 3 for reference. The increase in radii of semicircles indicates the impedance increases as the UV exposure time increases. This increase indicating an enhancement in the metal oxide resulting from the UV irradiation. In this data, a saturation stage is observed to occur at around the 15-minute UV exposure time.

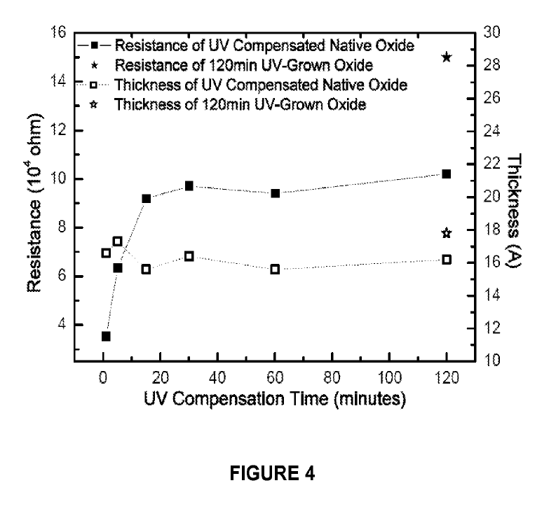

Referring to FIG. 4, an analysis was also conducted on the equivalent circuit models in FIG. 1 using equation (1) to extract the metal oxide film thicknesses and resistances. The data are plotted in FIG. 4, an evolution of the resistance and thickness of the UV-compensated native oxides was observed. As observed in FIG. 3, the resistance reaches about 98000Ω at a saturation point after about 15 minutes of UV compensation time (time of irradiation with UV light of a wavelength and power density substantially similar to that the Examples). Referring again to FIG. 4, the comparable thicknesses of all the films, within the range of about 1.6 to about 1.7 nm, indicates the oxide does not significantly thicken as the UV compensation time increases. Therefore, it is believed without being held to theory, that the quality of native oxide improvement observed with a 120-minute, UV-light compensation, results from a reduction in oxygen point defects. This belief is supported by the observed improvement in resistance from 17000Ω (120 minute, natural-grown oxide, Table 1) to 98000Ω (FIGS. 3 and 4).

It is believed, without being held to theory, that in accordance with the high resistance observed from the EIS spectra (e.g., in FIGS. 2 and 3 and in Table 1), the denser Al₂O₃ structure resulting from UV metal oxidation according to various aspects and embodiments of the present inventions, can provide improved resistance from corrosive chloride-ion attacks.

### EXAMPLES

The following examples and examples herein, are not exhaustive and should not be construed as limiting the scope of the present inventions in any way. Unless otherwise noted, the data of FIGS. 1-5 and Table 1 were obtained using procedures substantially as follows.

### Aluminum Films

Aluminum thin films were deposited on ultra-low-resistivity (100) silicon wafers by sputtering from an aluminum target at total pressure of 8 m Torr of argon. The base pressure of the sputtering chamber was approximately 4×10⁻⁹ Torr, and the thickness of the aluminum films was nearly 147 nm. Every silicon wafer, prior to aluminum deposition, was dipped in dilute hydrofluoric acid for two minutes, then rinsed in de-ionized water and dried in nitrogen to remove the native oxide and enable optimum electrical contact between the aluminum film and substrate.

### Ultraviolet Activated Oxidation of Metals

Following aluminum deposition, the sample was transferred into the load-lock of the sputtering chamber for photo-activated oxidation. The UV photon source was a UV lamp custom built into the load-lock to perform oxidation studies under controlled atmospheres and as a function of temperature. The source provided broadband UV radiation, providing photons with wavelengths in between approximately 185-365 nm at a power density of about 50 mW/cm². Various photon exposures, ranging from 1 to 120 minutes were performed at room temperature. Natural oxidation (i.e., with no exposure to UV light) at room temperature with identical oxygen pressures and times was performed on reference samples. A thin layer of amorphous Al₂O₃—also referred to as a native or natural oxide layer—usually forms on aluminum upon exposure to oxygen or air at room temperature.

### Electrochemical Characterization

The electrochemical corrosion test cell was filled with 0.5 M NaCl solution and included three electrodes: a reference electrode (saturated calomel electrode (SCE)), a counter electrode (graphite rod), and a working electrode (WE, the 147-nm aluminum on silicon wafer). Prior to EIS measurements, Porthole™ (manufactured by Gamry Instruments of Warminster, Pa.) was attached on each sample for an exact 3-cm² circular opening to face the 0.5-M NaCl solution electrolyte. Before the measurements were taken, the electrolyte was de-aerated in 99.99% nitrogen gas for 1 hour. To minimize the effect of native SiO₂ on the electrical connection of the working electrode, any un-deposited area (1 cm² on the edge of each sample) was cleaned with diluted helium fluoride (50:1) and de-ionized water.

EIS spectra on multiple samples were acquired at open circuit potential, about −0.77V, to minimize the effect of chemistry on the oxide film in the solution using our Solartron EIS system in the frequency range of 100 kHz to 0.01 Hz. The amplitude of the applied alternating current potential was 40 mV for all measurements. All measurements were performed on multiple samples to facilitate ensuring reproducible results. Tafel analysis was performed to obtain linear polarization measurements for each sample after the EIS measurements (the applied potential ranged from −0.5V to +0.5V, with reference to the open circuit potential). A scan rate of 1 mV/s was used for the potential applied to the test electrode.

All literature and similar material cited in this application, including, but not limited to, patents, patent applications, articles, books, treatises, and web pages, regardless of the format of such literature and similar materials, are expressly incorporated by reference in their entirety for all purposes. In the event that one or more of the incorporated literature and similar materials differs from or contradicts this application, including but not limited to defined terms, term usage, described techniques, or the like, this application controls.

The section headings used herein are for organizational purposes only and are not to be construed as limiting the subject matter described in any way.

While the present inventions have been described in conjunction with various embodiments and examples, it is not intended that the present inventions be limited to such embodiments or examples. On the contrary, the present inventions encompass various alternatives, modifications, and equivalents, as will be appreciated by those of skill in the art.

The inventions should not be read as limited to the described order or elements unless stated to that effect. It should be understood that various changes in form and detail may be made without departing from the scope of the present inventions. Therefore, all embodiments that come within the scope and spirit of the present inventions and equivalents thereto are claimed.

What is claimed is:

1. A method for providing a corrosion resistant oxide coating on a metal, comprising the steps of:
providing a substrate having a metal surface; and
irradiating the metal surface in the presence of oxygen with light having one or more wavelengths in the range between about 100 nm to 365 nm and a power density greater than about 10 mW/cm² to form an oxide layer on the metal surface.

2. The method of claim 1, wherein the metal surface comprises one or more of aluminum, chromium, iron, magnesium, titanium and alloys thereof.

3. The method of claim 1, wherein the partial pressure of oxygen during irradiation is in the range between about 1 mTorr to about 1000 Torr.

4. The method of claim 3, wherein the partial pressure of oxygen during irradiation is in the range between about 100 Torr to about 200 Torr.

5. The method of claim 1, wherein the power density of the irradiating light is greater than about 20 mW/cm².

6. The method of claim 5, wherein the power density of the irradiating light is greater than about 40 mW/cm².

7. The method of claim 1, wherein the step of irradiating the metal surface comprises irradiating the surface with substantially coherent light.

8. The method of claim 1, wherein the metal surface is irradiated for a time greater than about 10 minutes.

9. The method of claim 1, wherein the metal surface is irradiated for a time less than about four hours.

10. The method of claim 9, wherein irradiation of the metal surface forms an oxide layer having an impedance of greater than about 100,000 ohms.

11. The method of claim 9, wherein irradiation of the metal surface forms an oxide layer having an impedance that is at least five times greater than the impedance of an oxide layer formed without irradiating the metal surface with light having one or more wavelengths in the range between about 100 nm to 365 nm and a power density greater than about 10 mW/cm².

12. The method of claim 1, wherein prior to the step of irradiating the metal surface, the method comprises the step of:
cleaning the metal surface to substantially remove native oxide.

13. A method for improving the corrosion resistant of an oxide coating on a metal, comprising the steps of:
providing a metal surface having a metal oxide layer thereon
irradiating the metal oxide coating in the presence of oxygen to light having one or more wavelengths in the range between about 100 nm to 365 nm and a power density greater than about 10 mW/cm² to form a modified oxide layer on the metal surface.

14. The method of claim 13, wherein the metal surface comprises one or more of aluminum, chromium, iron, magnesium, titanium and alloys thereof.

15. The method of claim 13, wherein the partial pressure of oxygen during irradiation is in the range between about 1 mTorr to about 1000 Torr.

16. The method of claim 15, wherein the partial pressure of oxygen during irradiation is in the range between about 100 Torr to about 200 Torr.

17. The method of claim 13, wherein the power density of the irradiating light is greater than about 20 mW/cm².

18. The method of claim 17, wherein the power density of the irradiating light is greater than about 40 mW/cm².

19. The method of claim 13, wherein the step of irradiating the metal surface comprises irradiating the surface with substantially coherent light.

20. The method of claim 13, wherein the metal surface is irradiated for a time greater than about 10 minutes.

21. The method of claim 13, wherein the metal surface is irradiated for a time less than about four hours.

22. The method of claim 13, wherein irradiation of the metal surface forms an oxide layer having an impedance that is at least five times greater than the impedance of the metal oxide layer prior to irradiation.

23. The method of claim 13, wherein irradiation of the metal surface forms a modified oxide layer having a leakage current that is at least 10 times less than the leakage current of the metal oxide layer prior to irradiation.

24. The method of claim 13, wherein irradiation of the metal surface forms a modified oxide layer having a leakage current that is at least 100 times less than the leakage current of the metal oxide layer prior to irradiation.

25. The method of claim 13, wherein irradiation of the metal surface forms a modified oxide layer having a pitting potential that is at least 25% greater than the pitting potential of the metal oxide layer prior to irradiation.

26. A method for providing a corrosion resistant oxide coating on a metal surface while the metal surface to be coated is immersed in an aqueous solution, comprising the steps of:
providing a substrate having a metal surface, at least a portion of the metal surface being immersed in an aqueous solution; and
irradiating at least the portion of the metal surface immersed in water with light having one or more wavelengths in the range between about 100 nm to 365 nm and a power density greater than about 10 mW/cm² to form an oxide layer on the metal surface.

27. The method of claim 26, wherein the metal surface comprises one or more of aluminum, chromium, iron, magnesium, titanium and alloys thereof.

28. The method of claim 26, wherein the aqueous solution is salt water.

29. The method of claim 26, wherein the power density of the irradiating light is greater than about 20 mW/cm².

30. The method of claim 26, wherein the power density of the irradiating light is greater than about 40 mW/cm².

31. The method of claim 26, wherein the step of irradiating the metal surface comprises irradiating the surface with substantially coherent light.

32. The method of claim 26, wherein the metal surface is irradiated for a time greater than about 10 minutes.

33. The method of claim 26, wherein the metal surface is irradiated for a time less than about four hours.

34. The method of claim 26, wherein irradiation of the metal surface forms an oxide layer having an impedance that is at least five times greater than the impedance of an oxide layer formed without irradiating the metal surface with light having one or more wavelengths in the range between about 100 nm to 365 nm and a power density greater than about 10 mW/cm².

35. The method of claim 26, wherein irradiation of the metal surface forms an oxide layer having a leakage current that is at least 10 times less than the leakage current of an oxide layer formed without irradiating the metal surface with light having one or more wavelengths in the range between about 100 nm to 365 nm and a power density greater than about 10 mW/cm².

36. The method of claim 26, wherein irradiation of the metal surface forms an oxide layer having a leakage current that is at least 100 times less than the leakage current of an oxide layer formed without irradiating the metal surface with light having one or more wavelengths in the range between about 100 nm to 365 nm and a power density greater than about 10 mW/cm².

37. The method of claim 26, wherein irradiation of the metal surface forms an oxide layer having a pitting potential that is at least 25% greater than the pitting potential of an oxide layer formed without irradiating the metal surface with light having one or more wavelengths in the range between about 100 nm to 365 nm and a power density greater than about 10 mW/cm².
